(19) United States
(12) Patent Application Publication
(10) Pub. No.: US 2007/0108041 A1
(43) Pub. Date: May 17, 2007

(54) Magnetron source having increased usage life

(76) Inventor: George Xinsheng Guo, Palo Alto, CA (US)

Correspondence Address: Xin Wen, 3449 Rambow Drive, Palo Alto, CA, 94306, US

(21) Appl. No.: 11/272,540

(22) Filed: Nov. 11, 2005

(51) Int. Cl. C23C 14/32; C23C 14/00

(52) U.S. Cl. 204/192.1; 204/298.16

(57) ABSTRACT

A magnetron source for producing a magnetic field near a sputtering target in a vacuum deposition system includes a first group of sequentially positioned individual magnets of a first magnetic polarity, and a second group of sequentially positioned individual magnets of a second magnetic polarity opposite to the first magnetic polarity. The first group of magnets and the second group of magnets are so configured that electrons can be trapped near the sputtering surface of the sputtering target in the regions between the first group of magnets and the second group of magnets.

### CROSS REFERENCES TO RELATED APPLICATIONS

This application is related to commonly assigned U.S. patent application Ser. No. 11/185,241, titled “Single-process-chamber deposition system” by Guo, filed Jul. 20, 2005 and U.S. patent application Ser. No. 11/212,142, titled “Vacuum processing and transfer system” by Guo et al, filed Aug. 26, 2005, the contents of which are incorporated herein by reference.

### TECHNICAL FIELD

This application relates to apparatus for depositing material on substrate in a vacuum environment.

### BACKGROUND

Physical vapor deposition (PVD) is a process of sputtering materials off a target and depositing the sputtered materials on a substrate. The sputtering target and the substrate are positioned inside a vacuum envelope that can be filled with low-pressure gas such as Argon, Nitrogen, or Oxygen. Magnetrons are used in physical vapor deposition (PVD) to reduce the operating vacuum pressure and bias voltage by trapping energetic electrons in the magnetic field and hence increasing the path length of the electrons. The lengthened electron path increases the probability of ionizing gas atoms in the vacuum chamber and hence increases the plasma density. Magnetrons are typically placed behind the sputtering target.

A magnetron can include one or more pieces of magnets each consisting of two opposite magnetic poles. Inside the vacuum chamber, electrons can be trapped by the magnetic fields between the opposite magnetic poles of a magnet and form a plasma gas near the target surface. The attractive forces on the electrons are proportional to the tangential component of the magnetic field that is parallel to the target surface. The tangential component of the magnetic field reaches its maximum near the mid point between the two poles of a magnet. As a result, more electrons are trapped and form a higher density plasma near the mid regions between the opposite poles of a magnet. More target materials are thus sputter removed in the mid regions between the opposite poles of the magnets, resulting in uneven removal of target materials from the sputtering target.

FIG. 1 illustrates the erosion pattern in a target 100 by a circular magnetron 110 (although the magnetron can also be of other shapes). The sputtering occurs over the upper surface of the target 100. The magnetron 110 is placed behind the back surface of the target 100. The magnetron 110 includes two magnetic poles of opposite polarities: a circular shaped magnetic pole 120 in the center and a circular shaped magnetic pole 130 near the rim of the target 100. The magnetic field lines 115 are arc shaped as shown spanning between the two magnetic poles 120 and 130. After repeated sputtering operations, the uneven removal of the target material forms an erosion grove 140 between the two magnetic poles.

The uneven erosion can cause a target unusable even when there is still substantial target material left in a target. The shortened target life results in material waste and higher maintenance costs. In order to address the uneven erosion problem, some magnetron designs utilize the shape of the magnetic track to optimize the erosion profile. The improvement by these designs is limited because they still tend to leave large areas without magnetic track on the target surface. There is therefore a need to further reduce the erosion unevenness in the sputtering target in PVD systems.

### SUMMARY

Implementations of the system may include one or more of the following. In one aspect, the present invention relates to a magnetron source for producing a magnetic field near a sputtering target in a vacuum deposition system including a first group of sequentially positioned individual magnets of a first magnetic polarity, and a second group of sequentially positioned individual magnets of a second magnetic polarity opposite to the first magnetic polarity. The first group of magnets and the second group of magnets are so configured that electrons can be trapped near the sputtering surface of the sputtering target in the regions between the first group of magnets and the second group of magnets.

In another aspect, the present invention relates to a method for producing a magnetic field near the sputtering surface of a sputtering target in a vacuum deposition system, including positioning a first group of sequentially positioned individual magnets of a first magnetic polarity near a surface of the sputtering target opposite to the sputtering surface of the sputtering target, positioning a second group of sequentially positioned individual magnets of a second magnetic polarity opposite to the first magnetic polarity near the surface of the sputtering target opposite to the sputtering surface of the sputtering target, trapping electrons near the sputtering surface of the sputtering target in the regions between the first group of magnets and the second group of magnets, and sputtering target material off the sputtering target.

Embodiments may include one or more of the following advantages. The disclosed magnetron source improves the utilization of target materials, especially for a static magnetron. The disclosed magnetron source can lengthen the usage lifetime of the sputtering targets by increasing the uniformity of the erosion pattern, which reduces the cost for the target materials. The usage lifetime increase is especially prominent for magnetron sources that are stationary to the sputtering target during depositions.

In another aspect, the disclosed magnetron source provides the flexibilities of rearranging the electron path of sputtering source or for different targets. The magnetron designs can be optimized by placing individual magnets over entire target surface, so that the erosion on any point of the target surface can be adjusted by changing corresponding individual magnets. The redistribution of individual magnets can even out the material removal from the target and can also optimize the sputtering pattern in accordance with different materials. Sputtering uniformity and efficiency are improved. Equipment cost is also reduced where different targets are required in prior art systems.

In yet another aspect, the disclosed magnetron increases the ionization efficiency and increases the plasma density. This will reduce the operating pressure and lower the operating voltage, resulting in better plasma stability, higher deposition efficiency, and less chance of arcing inside the plasma.

The details of one or more embodiments are set forth in the accompanying drawings and in the description below. Other features, objects, and advantages of the invention will become apparent from the description and drawings, and from the claims.

### BRIEF DESCRIPTION OF THE DRAWINGS

FIG. 1 illustrates the erosion track in a typical prior art magnetron source.

FIG. 2A illustrates the layout of a magnetron source in accordance with the present invention.

FIG. 2B is a perspective view of the magnetron source in FIG. 2A.

FIG. 2C illustrates the path of electrons for the magnetron source as shown in FIG. 2A.

FIG. 3A illustrates a magnetron source 300 comprising ferromagnetic magnetic plates attached to the magnets of FIG. 2A.

FIG. 3A illustrates ferromagnetic magnetic plates that can be attached to the magnets of FIG. 2A.

FIG. 3B is a perspective view of a magnetron source 300 comprising the ferromagnetic magnetic plates of FIG. 3A attached to the magnets of FIG. 2A.

FIG. 4A illustrates the layout of the individual magnets in a rectangular shaped magnetron source in accordance with another embodiment of the present invention.

FIG. 4B is a perspective view of the rectangular shaped magnetron source of FIG. 4A.

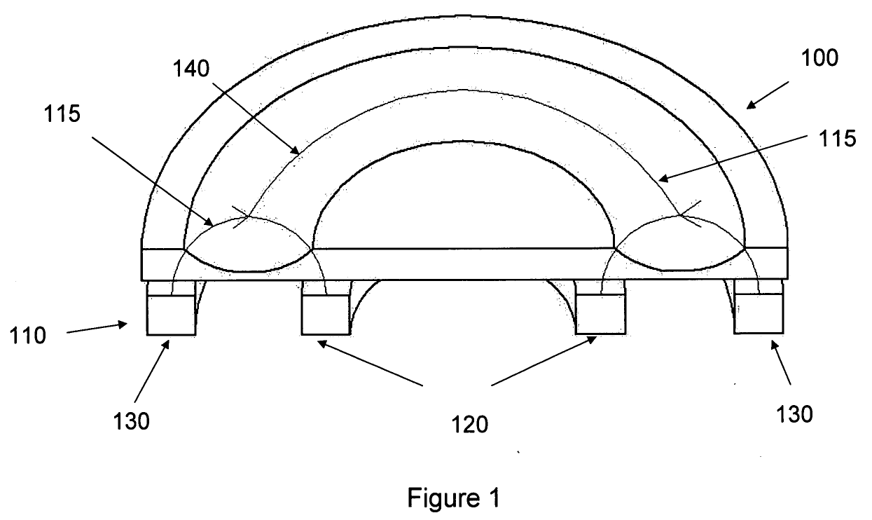

### DETAILED DESCRIPTION

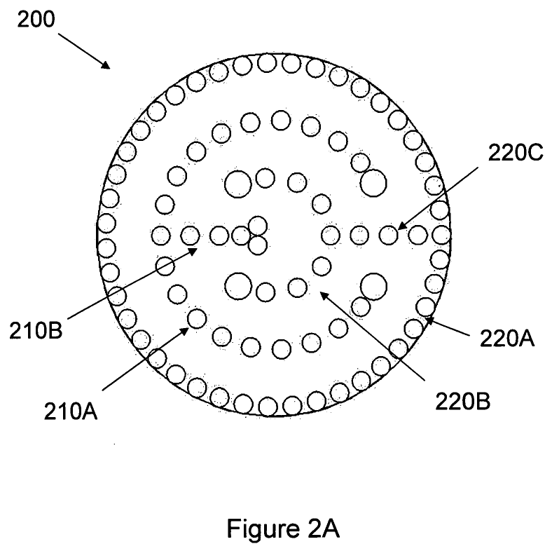

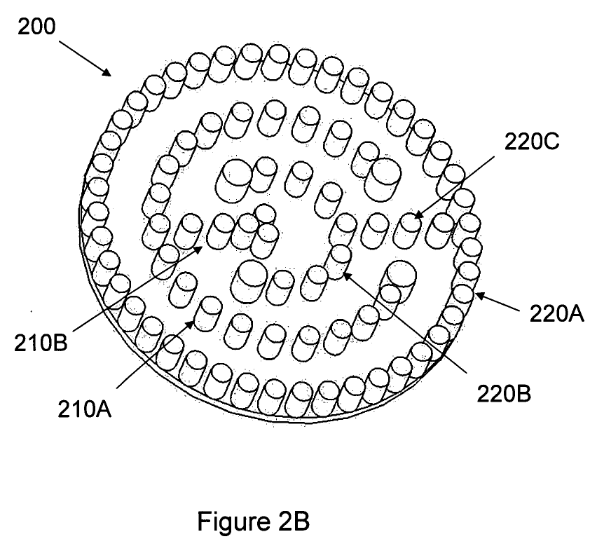

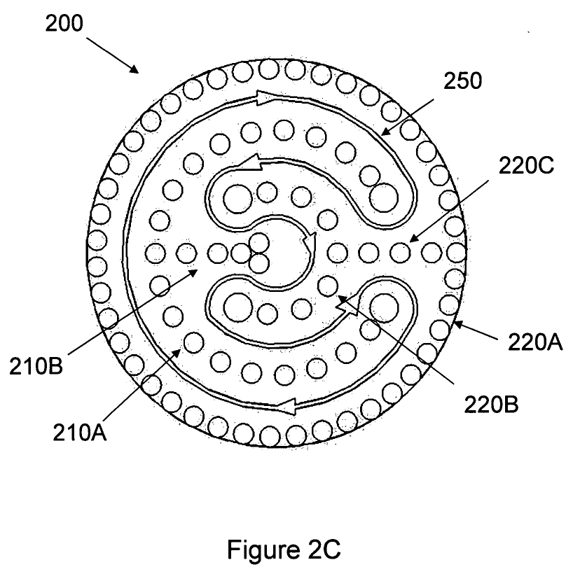

FIG. 2A illustrates the layout of a magnetron source 200 in accordance with the present invention. The magnetron source 200 includes a plurality of individual magnets 210A, 210B and 220A, 220B, 220C. The magnets 210A, 210B and the magnets 220A, 220B, 220C have opposite polarities. For example, the magnets 211A, 210B can be of south polarity whereas the magnets 220A, 220B, 220C can be of the north polarity. The magnets 210A, 210B, 220A, 220B, 220C can take the form of a circular disk, or a polygon-shaped tablet.

The magnets 210A, 210B are typically sequentially positioned with closer distances to each other with the group than from the magnets 220A, 220B, 220C. Similarly, the magnets 220A, 220B, 220C are typically closer positioned to each other with the group than from the magnets 210. In the example shown in FIG. 2A, the magnets 210A, 210B are distributed in a ring 210A and a closely positioned lateral branch 210B leading to the center. The magnets 220A, 220B, 220C form an outer ring 220A and an inner ring 220B that are bridged by a linear array of magnets 220C. FIG. 2B shows a perspective view of the magnetron source 200.

The magnets 210A, 210B and the magnets 220A, 220B, 220C are positioned close enough with each group to form a continuous path along which the tangential component of the magnetic field reaches its maximum. As such, more electrons are trapped in the areas between the two groups of individual magnets. FIG. 2C illustrates the path 250 of electrons in magnetron source 200. The electron path 250 is produced along the track of magnetic field between the barriers formed by the oppositely poled magnets 210A, 210B and magnets 220A, 220B, 220C. The electrons can bounce back and forth from the target surface and traverse along the path 250 until they lose most of their kinetic energies. The path 250 as shown forms a close loop to allow electrons to move continuously along the path 250. Abrupt end in magnetic track or the electron path 250 is avoided to prevent loss of electrons and plasma.

An advantage of the invented magnetron source 200 is that the number of the individual magnets, the spacing between the individual magnets, the number of rings in the distribution of the individual magnets, the size of the individual magnets, and the spacing between the two polarity groups of magnets can all easily be optimized to maximize target utilization, improve deposition uniformity, and improve plasma stability. As shown in FIG. 2A, the magnets 210A and 220B can include larger magnets at the ends of the lines to enhance the magnetic field strength in ending areas where larger open areas are involved. In addition, the magnetic strength at any point of the target and hence the erosion depth can be adjusted by changing the corresponding magnets nearby. This greatly increases the flexibility in the magnetron design.

Furthermore, various above described parameters can also be optimized in the magnetron source 200 specific to different the types of target materials to accommodate the difference in sputtering yield, scattering of sputtered materials with the gas atoms before reaching substrate, and angular sputtering distribution. For example, when the sputtering target material is changed, the individual magnets can be re-positioned using the same magnetron source 200, which can significantly reduce equipment development cost.

To optimize the erosion depth and maximize target utilization, the individual magnets 210A, 210B and 220A, 220B, 220C can be distributed to form a long electron path 250 and cover as much target surface as possible. More rings can be included in the distribution of the magnets 210A, 210B and 220A, 220B, 220C. A larger target surface area can be more evenly sputtered, which is highly desirable especially for the stationary magnetrons. In addition, the operating vacuum pressure and the bias voltage can also be lowered. Furthermore, the width of the magnetic field track can slightly vary along the electron path 250, which can further even out the erosion pattern and fill all available space above target surface.

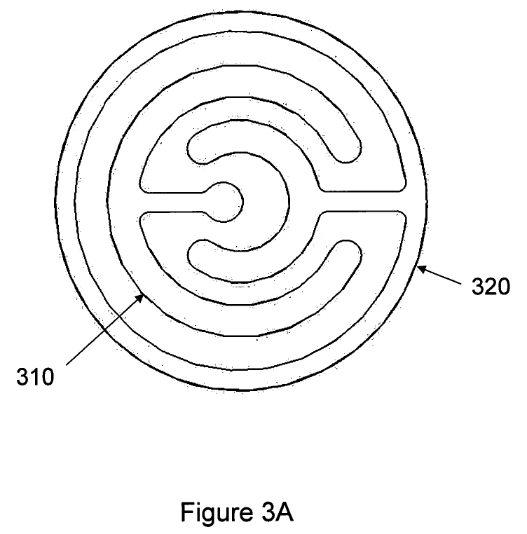

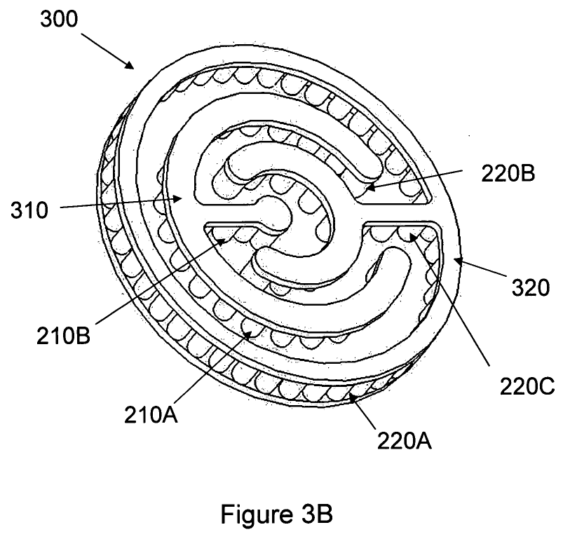

In another embodiment, a ferromagnetic material can be attached to a group of magnets of the same polarity to reduce the magnetic field variation. FIG. 3A shows two continuous pieces of ferromagnetic plates 310 and 320 that are shaped to cover the magnets 210A, 210B and magnets 220A, 220B, 220C, respectively. FIG. 3B is a perspective view of a magnetron source 300 that comprises the ferromagnetic plates 310 and 320 respectively attached to the individual magnets 210A, 210B and individual magnets 220A, 220B, 220C. Examples of the ferromagnetic material can include 400-series stainless steel, Mu-metal, etc.

In another embodiment, the magnetron sources 200 and 300 can be held stationary relative to the sputtering target or mounted on a rotation plate that can rotate relative to the sputtering target during the vacuum deposition. The distribution of the individual magnets can be optimized relative the rotation parameters to further reduce the uneven erosion in the target.

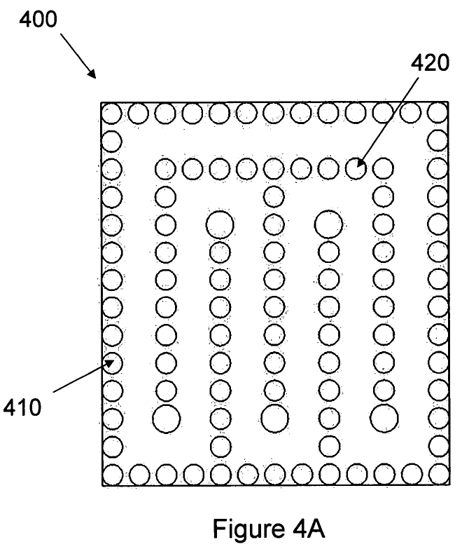

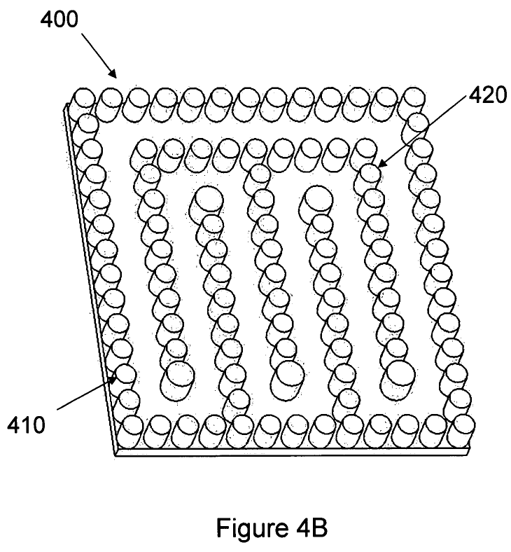

The invented magnetron source can be formed in other than circular shapes such as rectangles, polygons, or irregular shapes. FIG. 4A and FIG. 4B show a top view and a perspective view of a rectangular shaped magnetron source 400. The magnetron source 400 includes two groups of the individual magnets 410 and 420 that have a rectangular (e.g. square) outer boundary. The magnets 410 and 420 are distributed sequentially positioned in horizontal rows and vertical columns, forming a close-loop magnetic track between the two opposite polarity groups. Similar to previously described, the number, the sizes, the magnetic strength, and the spacing between individual magnets 410 and 420 can be optimized to minimize the erosion pattern.

In another embodiment, the distribution of individual magnets can be moved between different configurations during the lifetime of a target to further even out the residual uneven erosion in the target. For example, a magnetic track can be moved in a new configuration over the area where the magnets used to be positioned in the previous configuration. Material sputtering can thus catch up in the under-sputtered area on the target.

What is claimed is:

1. A magnetron source for producing a magnetic field near a sputtering target in a vacuum deposition system, comprising:
a first group of sequentially positioned individual magnets of a first magnetic polarity; and
a second group of sequentially positioned individual magnets of a second magnetic polarity opposite to the first magnetic polarity; wherein the first group of magnets and the second group of magnets are so configured that electrons can be trapped near the sputtering surface of the sputtering target in the regions between the first group of magnets and the second group of magnets.

2. The magnetron source of claim 1, wherein the first group of magnets and the second group of magnets are positioned adjacent to the surface of the sputtering target that is opposite to the sputtering surface.

3. The magnetron source of claim 1, wherein the first group of the magnets or the second group of magnets comprise magnets of different sizes or different magnetic strengths.

4. The magnetron source of claim 1, wherein the first group of magnets include a sequence of magnets that are distributed along at least a segment of a circle.

5. The magnetron source of claim 1, wherein the magnet at the end of the sequence of individual magnets in the first group comprises a large size or higher magnetic strength compared to the average size or the average magnetic strength of the magnets in the first group.

6. The magnetron source of claim 1, wherein the average distance between the magnets in the first group is smaller than the average distance between the magnets in the first group and the magnets in the second group.

7. The magnetron source of claim 1, wherein the regions between the first group of magnets and the second group of magnets forms a close-loop path for the trapped electrons.

8. The magnetron source of claim 7, wherein the close-loop path for the trapped electrons reach substantially the entire sputtering surface of the target.

9. The magnetron source of claim 1, wherein the first group of magnets are stationary relative to the sputtering target when the target material is being sputtered off the sputtering target.

10. The magnetron source of claim 1, wherein the first group of magnets and the second group of magnets can be moved by a transport mechanism relative to the sputtering target when the target material is being sputtered off the sputtering target.

11. The magnetron source of claim 1, wherein the first group of magnets and the second group of magnets comprise a substantially circular outer boundary or a substantially rectangular outer boundary.

12. The magnetron source of claim 1, further comprising a ferromagnetic material configured to be attached to the ends of plurality of magnets in the first group and/or the second group.

13. The magnetron source of claim 12, wherein the ferromagnetic material comprises one or more of a ferromagnetic stainless steel and a Mu-metal.

14. A method for producing a magnetic field near the sputtering surface of a sputtering target in a vacuum deposition system, comprising:
positioning a first group of sequentially positioned individual magnets of a first magnetic polarity near a surface of the sputtering target opposite to the sputtering surface of the sputtering target;
positioning a second group of sequentially positioned individual magnets of a second magnetic polarity opposite to the first magnetic polarity near the surface of the sputtering target opposite to the sputtering surface of the sputtering target;
trapping electrons near the sputtering surface of the sputtering target in the regions between the first group of magnets and the second group of magnets; and
sputtering target material off the sputtering target.

15. The method of claim 14, wherein the first group of sequentially positioned magnets or the second group of sequentially positioned magnets comprise magnets of different sizes, different shapes, or different magnetic strengths.

16. The method of claim 14, further comprising:
sequentially positioning a plurality of magnets in the first group of magnets along at least a segment of a circle.

17. The method of claim 14, further comprising:
placing an end magnet at the end of a sequence of the individual magnets in the first group, wherein the end magnet comprises a large size or higher magnetic strength compared to the average size or the average magnetic strength of the magnets in the first group.

18. The method of claim 14, wherein the average distance between the magnets in the first group is smaller than the average distance between the magnets in the first group and the magnets in the second group.

19. The method of claim 14, further comprising:
forming a close-loop path for the trapped electrons in the regions between the first group of magnets and the second group of magnets.

20. The method of claim 14, further comprising:
attaching a ferromagnetic material to the ends of a plurality of magnets in the first group.
